(19) United States
(12) Patent Application Publication
(10) Pub. No.: US 2025/0087632 A1
(43) Pub. Date: Mar. 13, 2025

(54) VOLTAGE REGULATOR IN SEMICONDUCTOR PACKAGES AND METHODS OF FORMING SAME

(71) Applicant: Taiwan Semiconductor Manufacturing Co., Ltd., Hsinchu (TW)

(72) Inventors: Chih-Chao Chou, Hsinchu (TW); Ching-Wei Tsai, Hsinchu (TW); Yi-Hsun Chiu, Zhubei City (TW)

(21) Appl. No.: 18/405,718

(22) Filed: Jan. 5, 2024

Related U.S. Application Data
(60) Provisional application No. 63/582,010, filed on Sep. 12, 2023.

(51) Int. Cl. H01L 25/065; H01L 21/768; H01L 23/00; H01L 23/48; H01L 23/528

(52) U.S. Cl. CPC H01L 25/0652; H01L 21/76898; H01L 23/481; H01L 23/5286; H01L 24/08; H01L 24/16; H01L 24/80; H01L 2224/08145; H01L 2224/16225; H01L 2224/80895; H01L 2224/80896; H01L 2225/06548

(57) ABSTRACT

A semiconductor package includes a first semiconductor die and a second semiconductor die bonded over the first semiconductor die. The second semiconductor die includes a first backside interconnect structure having a first power rail structure. An integrated voltage regulator die is bonded over the second semiconductor die such that the integrated voltage regulator die is electrically connected to the first power rail structure. A through via is on the first semiconductor die and is electrically coupled to the first semiconductor die. The through via is disposed outside of and adjacent to the second semiconductor die. The through via also electrically couples the first semiconductor die to the second semiconductor die through the integrated voltage regulator die.

### PRIORITY CLAIM AND CROSS-REFERENCE

This application claims the benefit of U.S. Provisional Application No. 63/582,010, filed on Sep. 12, 2023, entitled “SPR (Super Power Rail) with IVR (Integrated Voltage Regulator) in SolC,” which is incorporated herein by reference.

### DISCUSSION OF THE BACKGROUND

The semiconductor industry continues to improve the integration density of various electronic components (e.g., transistors, diodes, resistors, capacitors, etc.) by continual reductions in minimum feature size, which allow more components, hence more functions, to be integrated into a given area. When creating semiconductor packages having a top die and a bottom die, the top die may need to be electrically connected to the bottom die. Formation of power through silicon vias (TSV) may need more processing steps, may occupy more area, and may increase cost in making CPU top die. It is high desirable to reduce the area and cost and improve the form factor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F illustrate the cross-sectional views of intermediate stages of a semiconductor device in the formation of a package and top views of the semiconductor device, in accordance with some embodiments of the disclosure.

FIGS. 2A, 2B, and 2C illustrate the cross-sectional views of intermediate stages for producing a semiconductor die that includes a semiconductor device, a metallization layer and a power rail structure.

FIG. 3 illustrates the cross-sectional view of a metallization layer.

FIG. 4 illustrates the cross-sectional view of a semiconductor package, in accordance with some embodiments of the disclosure.

FIG. 5 illustrates the cross-sectional views of a semiconductor package, in accordance with some embodiments of the disclosure.

FIG. 6 illustrates a flow diagram of a process for generating a semiconductor package, according to some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, two semiconductor dies, one attached on top of the other may be electrically connected to each other. In some embodiments, a first semiconductor die that includes a central processing unit (CPU) or includes a graphic processing unit (GPU) is attached, e.g., is bonded, over a second semiconductor die that includes a random-access memory (RAM) circuit and/or a static RAM (SRAM) circuit. In some embodiments, one or more TSVs or a TSV tower for transferring power, e.g., power TSVs, are arranged outside the semiconductor die having the CPU.

The power may be regulated by an integrated voltage regulator (IVR) that is attached to a power rail structure, e.g., a power rail or a super power rail (SPR), that is inside the semiconductor die. The IVR may receive the power from a power source unit (PSU) and provide a regulated power, e.g., regulated voltage and current, to one or more semiconductor dies that may include the semiconductor die that has the CPU/GPU. In some embodiments, the IVR is connected by one or more vias that extend through a dielectric layer, e.g., an insulating or encapsulant layer, outside the semiconductor die that includes the CPU/GPU. Thus, each via of the one or more vias is a through dielectric via (TDV) that is connected between the IVR and another semiconductor die, e.g., the semiconductor die that includes the SRAM and, thus, the power is provided by the TDV to the other semiconductor die. Implementing the one or more TDVs that is arranged outside the semiconductor die that has the CPU/GPU, may reduce the processing steps and cost of packaging and also may improve the form factor.

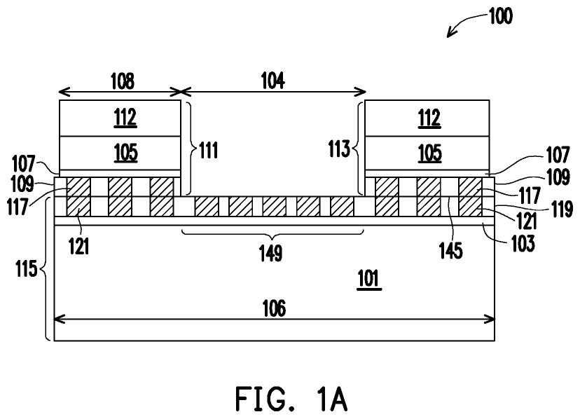

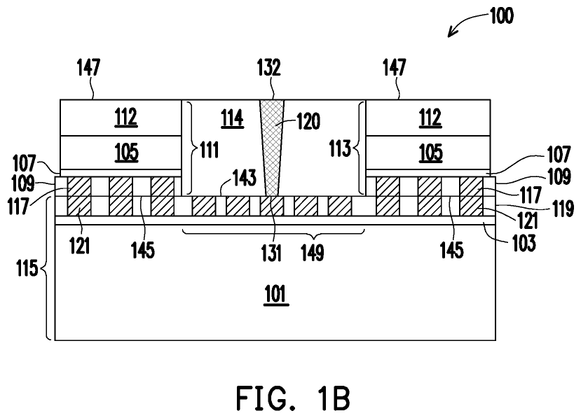

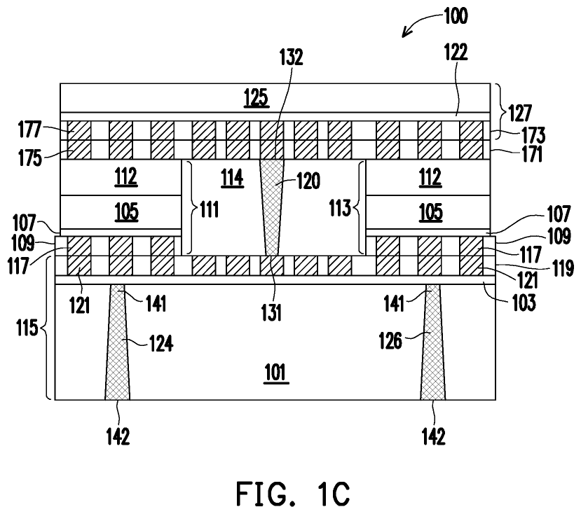

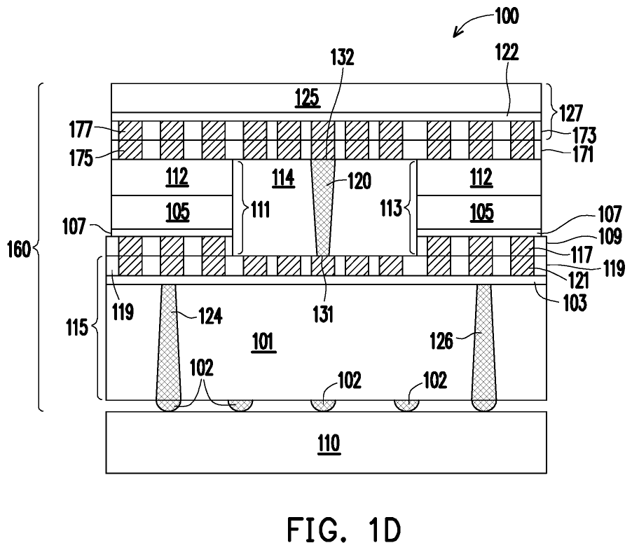

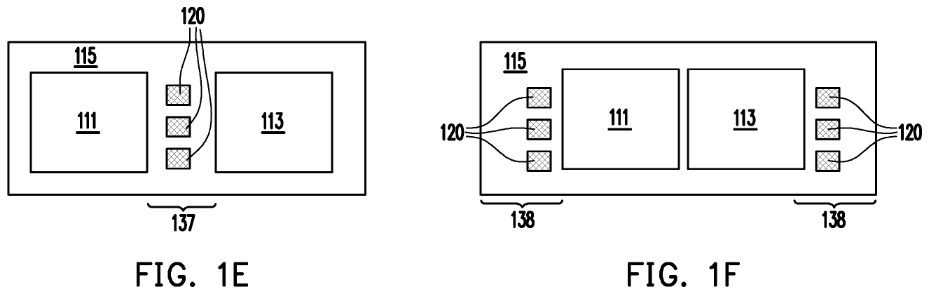

FIGS. 1A, 1B, 1C, 1D, 1E, and 1F illustrate the cross-sectional views of intermediate stages of a semiconductor device in the formation of a package 160 and top views of the semiconductor device, in accordance with some embodiments of the disclosure. FIG. 1A shows a semiconductor device 100 that includes a semiconductor die 111 that is bonded, e.g., connected to a semiconductor die 115. FIG. 1A also shows a semiconductor die 113 that is bonded to the semiconductor die 115. The semiconductor dies 111 and 113 are bonded to the semiconductor die 115 via a face-to-face bonding, e.g., a metal-to-metal bonding and dielectric-to-dielectric bonding as explained in greater detail below.

As shown, each one of the semiconductor dies 111 and 113 include a backside interconnect structure 112 at the top and a front-side interconnect structure 107 at the bottom. The backside interconnect structure 112 may include a power rail structure for power delivery in the semiconductor dies 111 and 113. In some embodiments, each one of the semiconductor dies 111 and 113 include a semiconductor device layer 105, which may include active devices (e.g., transistors) that are interconnected together by the backside interconnect structure 112 to provide functional circuitry. For example, each one of the semiconductor dies 111 and 113 may provide logic circuitry (e.g., a central processing unit (CPU), a graphic processing unit (GPU), or the like) in the completed semiconductor package. The semiconductor die 115 includes a front-side interconnect structure 103 at the top such that the face-to-face bonding is connected between the front-side interconnect structure 103 of the semiconductor die 115 and the front-side interconnect structure 107 of the semiconductor dies 111 and 113. In some embodiments, the package 160 has one of the semiconductor die 111 or the semiconductor die 113. Alternatively, the package 160 may include additional semiconductor dies at a same level as the semiconductor dies 111 and 113.

Further, each one of the semiconductor dies 111 and 113 includes an insulating bonding layer 109 on the front-side interconnect structure 107, and bond pads 117 that are formed in an insulating bonding layer 109. The bond pads 117 may be conductive pillars, pads, or the like, to which external connections are made. The bond pads 117 can be formed of a metal, such as copper, aluminum, or the like, and can be formed by, for example, by plating, or the like. In some embodiments, the bond pads 117 may be electrically connected to conductive features of the front-side interconnect structure 107 by conductive vias (sometimes referred to as bond pad vias). The insulating bonding layer 109 may be made of a material suitable for subsequent dielectric-to-dielectric bonding, such as, silicon oxide, silicon oxynitride, or the like. The insulating bonding layer 109 may be deposited on the front-side interconnect structure 107, for example, by spin coating, lamination, chemical vapor deposition (CVD), or the like. A planarization process (e.g., a chemical mechanical polish (CMP) or the like) may be performed such that top surfaces of the bond pads 117 and the insulating bonding layer 109 are coplanar (within process variations). As will be described in greater detail below, the planarized bottom surfaces 145 of the semiconductor dies 111 and 113 are bonded to the underlying semiconductor die 115.

The semiconductor die 115 includes a semiconductor device layer 101 and the front-side interconnect structure 103. The semiconductor device layer 101 may include active devices (e.g., transistors) disposed at a top surface of a semiconductor substrate, and the active devices of the semiconductor device layer 101 may be interconnected together by the front-side interconnect structure 103 to provide functional circuitry. For example, each one of the semiconductor dies 111 and 113 may provide memory circuitry (e.g., a static random access memory (SRAM) circuitry, dynamic random access memory (DRAM) circuitry, or the like) in the completed semiconductor package. The semiconductor die 115 further includes an insulating bonding layer 119 on the front-side interconnect structure 103, and bond pads 121 that formed in an insulating bonding layer 119. The bond pads 121 and the insulating bonding layer 119 may be formed of like materials using like processes as the bond pads 117 and the insulating bonding layers 109, respectively, as described above. In some embodiments, a planarization process (e.g., a chemical mechanical polish (CMP) or the like) may be performed such that top surfaces of the bond pads 121 and the insulating bonding layer 119 are coplanar (within process variations).

As shown in FIG. 1A, the semiconductor dies 111 and 113 are bonded side-by-side on a top surface of the semiconductor die 115 with a gap therebetween. The semiconductor dies 111 and 113 and the semiconductor die 115 are directly bonded in a face-to-face manner by a dielectric-to-dielectric bonding and metal-to-metal bonding processes (sometimes referred to as hybrid bonding), such that the front sides of the semiconductor dies 111 and 113 are bonded side-by-side to the front side of the semiconductor die 115 with a gap therebetween. Specifically, the insulating bonding layers 109 of the semiconductor dies 111 and 113 are bonded to the insulating bonding layer 119 on the semiconductor die 115 through dielectric-to-dielectric bonding, without using any adhesive material (e.g., die attach film), and the bond pads 117 of the semiconductor dies 111 and 113 are bonded to the bond pads 121 on the semiconductor die 115 through metal-to-metal bonding, without using any eutectic material (e.g., solder). The bonding may include a surface activation, a pre-bonding, and an annealing. The surface activation may include activating the insulating bonding layers 109 and/or 119 may be performed using, e.g., a dry treatment, a wet treatment, a plasma treatment, exposure to H₂, exposure to N₂, exposure to O₂, combinations of these, or the like. In embodiments where a wet treatment is used, an RCA cleaning process may be used, for example. Through the activation treatment, the number of OH groups at surface(s) of the insulating bonding layers 109 and/or 119 increases. After surfaces of the insulating bonding layers 109 and/or 119 are activated, a pre-bonding is performed by applying a small pressing force to press the semiconductor dies 111 and 113 against the semiconductor die 115. The pre-bonding is performed at a low temperature, such as room temperature, such as a temperature in the range of about 15° C. to about 30° C. The bonding strength of the insulating bonding layers 109 and 119 is then improved in a subsequent annealing step, in which the insulating bonding layers 109 and 119 are annealed at a high temperature, such as a temperature in the range of about 100° C. to about 450° C. After the annealing, bonds, such as covalent bonds, are formed bonding the insulating bonding layers 109 and 119. The bond pads 117 and 121 may be in physical contact after the pre-bonding, or may expand to be brought into physical contact during the annealing. Further, during the annealing, the material of the bond pads 117 and 121 (e.g., copper) intermingles, so that metal-to-metal bonds are also formed. Hence, the resulting bonds are hybrid bonds that include both dielectric-to-dielectric bonds and metal-to-metal bonds. As a result, the circuitry within the semiconductor dies 111 and 113 may be electrically connected to circuitry within the semiconductor die 115 through the bond pads 117 and 121.

As a result of the bonding, a portion 149 of the semiconductor die 115, e.g., a portion of the front-side interconnect structure 103 of the semiconductor die 115, is not covered by the semiconductor dies 111 and 113 and a subset of the bond pads 121 may be exposed. In some embodiments, the semiconductor die 115 has a width 106, and the semiconductor die 111 has a width 108 that is shorter than the width 106. In some embodiments, the total width of the semiconductor dies 111 and 113 is smaller than the width 106 of the semiconductor die 115. Thus, the portion 149 not covered by the semiconductor dies 111 and 113 has a width 104.

FIG. 1B shows the semiconductor device 100 that additionally includes a bottom surface 145, e.g., a first surface, of the semiconductor dies 111 and 113 and also shows a top surface 147, e.g., a second surface, of the semiconductor dies 111 and 113. The semiconductor device 100 also shows the top surface 143, e.g., the first surface, of the semiconductor die 115. Additionally, the face-to-face bonding is between the top surface 143 of the front-side interconnect structure 103 and the bottom surface 145 of the front-side interconnect structure 107 of the semiconductor dies 111 and 113.

FIG. 1B shows that the portion 149 on top of the semiconductor die 115 is covered with an insulating layer 114 such that the insulating layer 114 is also in contact with the semiconductor dies 111 and 113. For example, in some embodiments, the insulating layer 114 comprises a dielectric, gap fill material, such as silicon oxide, silicon nitride, silicon oxynitride, silicon oxycarbonitride, combinations thereof, or the like that is deposited by physical vapor deposition (PVD), chemical vapor deposition (CVD), or the like. In some embodiments, the insulating layer 114 is a molding material or compound that is formed by compression molding, transfer molding, or the like followed by a curing process. The molding material may or may not include filler materials (e.g., silica fillers). A planarization process may be performed to planarize the top surface of the insulating layer 114 and the semiconductor dies 111 and 113. The planarization process may be a CMP, an etch-back, combinations thereof, or the like. The insulating layer 114 extends from a top surface 143 of the insulating bonding layer 119 to the top surface 147 of the semiconductor dies 111 and 113 and, thus, the insulating layer 114 has a top surface at the level of the top surface 147.

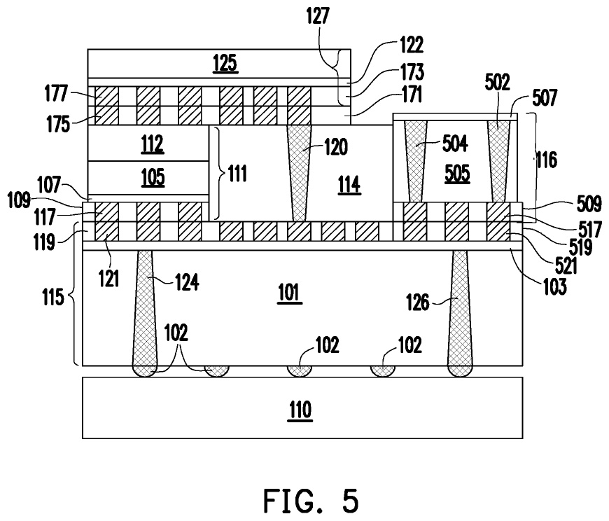

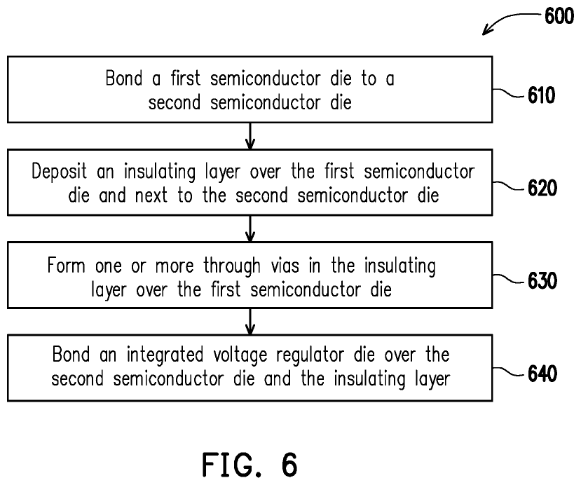

In addition, through vias 120 extend through the height of the insulating layer 114. In embodiments where the insulating layer 114 is made of a dielectric material, the through vias 120 may be referred to as a TDV. As an example to form the through vias 120, openings may be etched through the insulating layer 114 using, for example, a combination of photolithography and etching. The openings may expose certain ones or the bond pads 121. Then, a conductive material (e.g., a metal such as copper or the like) may be filled in the openings to form the through vias 120. Each through via 120 is electrically coupled, e.g., electrically connected, from a first end 131 of the through vias 120 to a bond pad 121 at the top surface 143 of the semiconductor die 115. In addition, a second end 132 of each through via 120 extends to a height of the insulating layer 114, which is the top surface 147. FIGS. 5 and 6 describe the distribution of the through vias 120 over the semiconductor die 115.

Next, in FIG. 1C, an insulating bonding layer 171 having bond pads 175 disposed therein that is formed over the semiconductor dies 111 and 113 as well as the insulating layer 114 and the through vias 120. The bond pads 175 may be conductive pillars, pads, or the like, to which external connections are made. The bond pads 175 are similar to the bond pads 117 and 121 described above. In some embodiments, the bond pads 175 and/or the bond pads 177 may be electrically connected to conductive features of the backside interconnect structure 112 (e.g., power rail structures) by conductive vias. The insulating bonding layer 171 may be made of a material suitable for subsequent dielectric-to-dielectric bonding and are similar to insulating bonding layer 109 or 119. A planarization process (e.g., a chemical mechanical polish (CMP) or the like) may be performed such that top surfaces of the bond pads 175 and the insulating bonding layer 171 are coplanar (within process variations). In some embodiments, the insulating layer 114 is in contact with the insulating bonding layer 171 that includes bond pads 175 that are formed in the insulating bonding layer 171. In some embodiments, the second end 132 of each through via 120 is electrically connected to a bond pad 175.

As further illustrated by FIG. 1C, an integrated voltage regulator die 127 may be bonded to the semiconductor dies 111 and 113 as well as the through vias 120. The integrated voltage regulator die 127 may include a semiconductor substrate 125, e.g., a semiconductor device layer, having active devices disposed thereon and a front-side interconnect structure 122 that electrically connects the active devices to form one or more functional circuits, such as IVR circuits. The integrated voltage regulator die 127 further includes an insulating bonding layer 173 connected to the front-side interconnect structure 122 and bond pads 177 that are formed in the insulating bonding layer 173. The insulating bonding layer 173 and the bond pads 177 may be made of a like material using like processes as the insulating bonding layer 109 and the bond pads 117, respectively, discussed above. The insulating bonding layer 173 and the bond pads 177 may be directly bonded to the insulating bonding layer 171 and the bond pads 175 using a dielectric-to-dielectric and metal-to-metal bonding process described above (e.g., the bonding process used to bond the semiconductor dies 111 and 113 to the semiconductor die 115). The planarized insulating bonding layer 173 is bonded to the top surfaces 147 of the semiconductor dies 111 and 113. In some embodiments, the integrated voltage regulator die 127 receives a voltage from a power supply unit (PSU), regulates the voltage, and provides a regulated voltage, e.g., a stable voltage, via the backside interconnect structure 112, to the semiconductor dies 111 and 113. In some embodiments, the second end 132 of the through vias 120 are connected to the front-side interconnect structure 122 of the integrated voltage regulator die 127 and the integrated voltage regulator die 127 receives a voltage, e.g., an unregulated voltage, from a power source unit by a through via 120. For example, a voltage and a current of the integrated voltage regulator die 127 is received by the bond pad 175 and is transferred to through via 120.

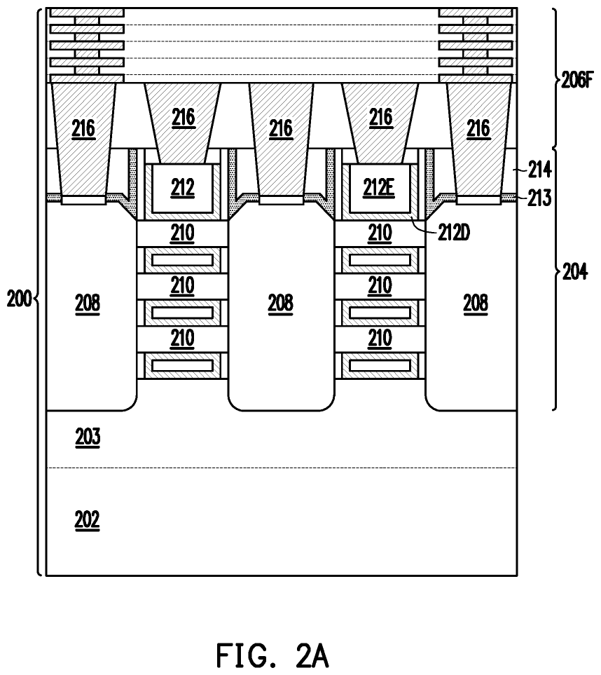

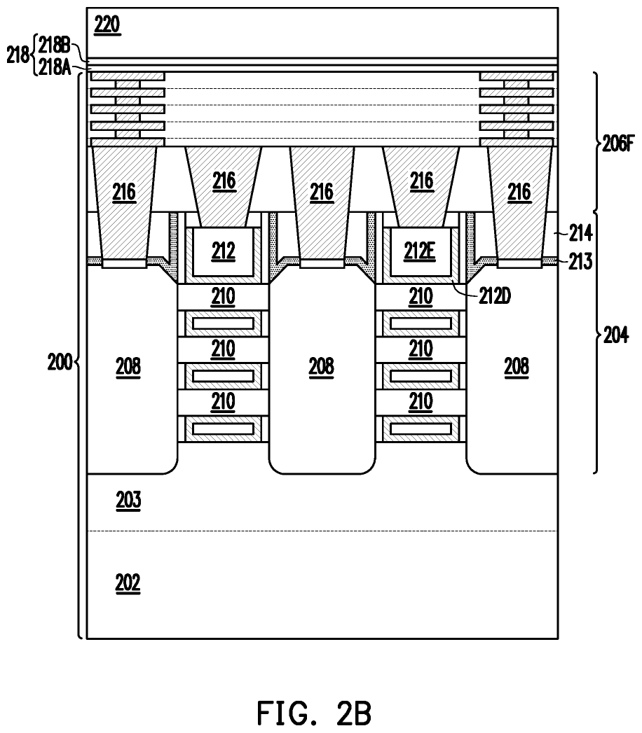

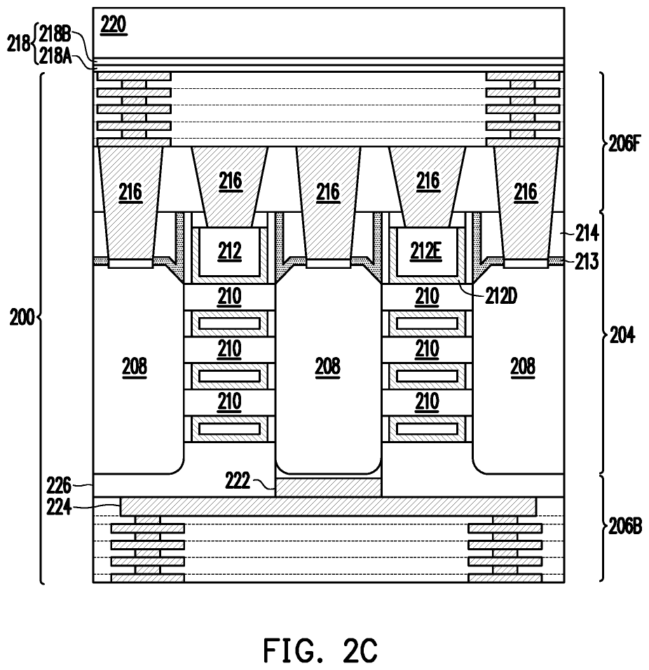

In some embodiments, the integrated voltage regulator die 127 provides a constant power, e.g., a constant voltage with the current for each device in the semiconductor die, such as the CPU, the GPU, or the SRAM of the semiconductor dies 111, 113, and 115. The CPU, the GPU, and the SRAM may be sensitive to voltage fluctuation or insufficient current. Thus, for reliable performance, the integrated voltage regulator die 127 is implemented in the semiconductor die that the CPU is located. In some embodiments, the CPU consumes considerable energy of about few tens of watts or even more than a hundred watts when performing calculation intensive tasks. When performing calculation intensive tasks, lack of sufficient current or a voltage drop may reduce CPU clock cycle and damage performance or even shut down the CPU. Thus, the integrated voltage regulator die 127 is used to provide reliable performance by the CPU. In some embodiments, the integrated voltage regulator die 127 generates the reliable voltage when receives a current and voltage from a power source unit and provides the reliable power through the backside interconnect structure 112 to one or more CPU/GPU of the semiconductor dies 111 and 113 and by one or more through vias 120 to SRAM of the semiconductor die 115. In some embodiments, the backside interconnect structure 112 includes a power rail structure. The power rails may be made wider than the connection lines of the die to reduce the ohmic drop when the current is provided for the sensitive devices such as a CPU or a SRAM. The power rail structure is described with respect to FIG. 2C.

In some embodiments, the regulated power is provided from the integrated voltage regulator die 127 through the backside interconnect structure 112 to the semiconductor dies 111 and 113. Also, the regulated power is provided from the integrated voltage regulator die 127 by the through vias 120 to the semiconductor die 115. In some embodiments, signal communication between the semiconductor dies 111 and 113 and the semiconductor die 115 is done through the bond between the front-side interconnect structure 103 and the front-side interconnect structure 107. Implementing the through vias 120 outside the semiconductor die that has the top semiconductor device, e.g., CPU or GPU, may reduce the processing steps and cost of packaging and also may improve the form factor.

FIG. 1C further includes through vias 124 and 126 that extend a height of the semiconductor die 115 and connects a first end 141, the narrower end, of the through vias 124 and 126 to the front-side interconnect structure 103 of the semiconductor die 115. A second end 142, the wider end, of the through vias 124 and 126 is at the bottom of the semiconductor die 115.

FIG. 1D shows the semiconductor device 100 that in addition to FIG. 1C includes two or more connector bumps 102. The connector bumps 102 are connected to the bottom of the semiconductor die 115 and may be connected to the second end 142 of the through vias 124 and 126. FIG. 1D also shows a printed circuit board, a PCB 110, that is electrically connected to the semiconductor die 115 via the connector bumps 102. In some embodiments, the PCB 110 provides a voltage from a power supply unit. The provided voltage may be connected through the connector bumps 102, one or both of the through vias 124 and 126, the front-side interconnect structure 103, and the through via 120 to the integrated voltage regulator die 127. The provided voltage is then regulated by the integrated voltage regulator die 127 as described above. The connector bumps 102 may also provide communication between the PCB 110 and the semiconductor die 115, the semiconductor die 111, and the semiconductor die 113. FIG. 1D also shows the package 160, e.g., a semiconductor device package, that is coupled to the PCB 110.

FIGS. 1E and 1F illustrate top views of the semiconductor package of FIG. 1B, in accordance with some embodiments of the disclosure. FIGS. 1E and 1F show the semiconductor dies in and 113 that are arranged over the semiconductor die 115 and two or more through vias 120 that are arranged on the semiconductor die 115 and outside the area covered by the semiconductor dies in and 113. FIG. 1E is similar to FIGS. 1B, 1C, and 1D because the through vias 120 are arranged in a portion 137, e.g., a segment, between the semiconductor dies in and 113. However, FIG. 1F is different because the through vias 120 are arranged at the end portions 136 and 138 that are at the sides of the semiconductor dies in and 113 that are not facing each other. In some embodiments, the insulating layer 114 is deposited over the portions 136, 137, and 138 on the semiconductor die 115 and the through vias 120 extend in the insulating layer.

FIGS. 2A, 2B, and 2C illustrate the cross-sectional views of intermediate stages for producing a semiconductor die that includes a semiconductor device, a metallization layer and a power rail structure. In some embodiments, the metallization layer is a from-side metallization layer and the power rail structure is a backside power rail structure. The stages of FIGS. 2A, 2B, and 2C may be used for producing the semiconductor die 111 and the semiconductor die 113. Thus, in the following discussion of FIGS. 2A, 2B, and 2C, a device layer 204 in FIGS. 2A, 2B, and 2C is consistent with the semiconductor device layer 105 of FIGS. 1A, 1B, 1C, and 1D. A backside interconnect structure 206B in FIG. 2C that includes a power rail is consistent with backside interconnect structure 112, and a front-side interconnect structure 206F of FIGS. 2A, 2B, and 2C is consistent with the front-side interconnect structure 107 of FIGS. 1A, 1B, 1C, and 1D.

FIGS. 2A, 2B, and 2C illustrate exemplar details of intermediate processing steps for forming an integrated circuit die 200, e.g., a semiconductor die, that includes a backside power rail. The integrated circuit die 200 may be initially formed as part of a wafer that is subsequently singulated. Referring first to FIG. 2A, the integrated circuit die 200 includes a semiconductor substrate 202, such as silicon, doped or undoped, or an active layer of a semiconductor-on-insulator (SOI) substrate. The semiconductor substrate 202 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 202 has an active surface (e.g., the surface facing upwards in FIG. 2A), sometimes called a front-side, and an inactive surface (e.g., the surface facing downwards in FIG. 2A), and sometimes called a backside.

The device layer 204 is formed at the front-side (i.e., the active surface) of the semiconductor substrate 202. The device layer 204 may include active devices (e.g., transistors, diodes, etc.), capacitors, resistors, etc. In some embodiments, the active devices of the device layer 204 includes Nano-FETs (e.g., nanowire field effect transistors (FETs), Nano-sheet FETs (Nano-FETs), or the like). The Nano-FETs comprise nanostructures 210 (e.g., Nano-sheets, nanowire, or the like) over fins 203 that extend upwards from the base substrate 202, and the nanostructures 210 act as channel regions for the Nano-FETs. The nanostructures 210 may include p-type nanostructures, n-type nanostructures, or a combination thereof.

Gate stacks 212 (including gate dielectric layers 212D and gate electrodes 212E) are disposed over top surfaces of the fins 203 and along top surfaces, sidewalls, and bottom surfaces of the nanostructures 210. The gate dielectric layers 212D may be disposed between the gate electrodes 212E and the nanostructures 210. Epitaxial source/drain regions 208 are disposed on the fins 203 on opposing sides of the gate stacks 212, and the nanostructures 210 may extend between adjacent epitaxial source/drain regions 208. Source/drain regions 208 may refer to a source or a drain, individually or collectively dependent upon the context. The device layer 204 may include other types of transistors (e.g., fin field effect transistors (FinFETs) or the like) as well.

An inter-layer dielectric, e.g., an ILD 214, is formed over the front-side of the semiconductor substrate 202. The ILD 214 surrounds and covers the devices of the device layer 204. The ILD 214 may include one or more dielectric layers formed of materials such as silicon oxide, silicon oxynitride, silicon oxycarbonitiride, Phospho-Silicate Glass (PSG), Boro-Silicate Glass (BSG), Boron-Doped Phospho-Silicate Glass (BPSG), undoped Silicate Glass (USG), or the like. The ILD 214 may be deposited by CVD, ALD, PVD, or the like. In some embodiments, a contact etch stop layer, e.g., a CESL 213, comprising silicon nitride or the like, may be disposed between the ILD 214 and the devices of the device layer 204.

Conductive plugs 216 extend through the ILD 214 and the CESL 213 to electrically and physically couple the devices of the device layer 204. For example, the conductive plugs 216 may couple the gate stacks 212 and source/drain regions 208. In some embodiments, silicide regions may be disposed at the interfaces between the conductive plugs 216 and the source/drain regions 208. The conductive plugs 216 may be formed of tungsten, cobalt, nickel, copper, silver, gold, aluminum, the like, or combinations thereof. Because the conductive plugs 216 are disposed on the front-side of the substrate 202, they may also be referred to as conductive plugs 216, e.g., front-side contacts.

The front-side interconnect structure 206F is disposed over the ILD 214 and conductive plugs 216. The front-side interconnect structure 206F interconnects the devices of the device layer 204 to form integrated circuits. The front-side interconnect structure 206F includes, for example, metallization patterns in one or more dielectric layers. The metallization patterns include metal lines and vias formed in one or more low-k dielectric layers with damascene processes, for example. The metallization patterns of the front-side interconnect structure 206F are electrically coupled to the devices of the device layer 204 by the conductive plugs 216.

In FIG. 2B, a carrier substrate 220 is bonded to a top surface of the front-side interconnect structure 206F by first and second bonding layers 218A and 218B. The carrier substrate 220 may be a glass carrier substrate, a ceramic carrier substrate, a wafer (e.g., a silicon wafer), or the like. The carrier substrate 220 may provide structural support to the integrated circuit die 200 during subsequent processing steps and in the completed device. The first bonding layer 218A and the second bonding layer 218B may be deposited on the front-side interconnect structure 206F and the carrier substrate 220, respectively by any suitable process, such as PVD, CVD, ALD, or the like. The first bonding layer 218A and the second bonding layer 218B may each comprise an insulating material that is suitable for a dielectric-to-dielectric bonding process. Example materials for the first bonding layer 218A and the second bonding layer 218B include silicon oxide (e.g., SiO₂), silicon nitride, silicon oxynitride, silicon carbonitride, silicon oxycarbonitride, or the like.

After the first and second bonding layers 218A and 218B are deposited, the carrier substrate 220 may be bonded to the front-side interconnect structure 206F using a suitable technique, such as dielectric-to-dielectric bonding, or the like. The dielectric-to-dielectric bonding process may include applying a surface treatment to one or more of the first bonding layer 218A and the second bonding layer 218B. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the first and second bonding layers 218A and 218B. The carrier substrate 220 is then aligned with the front-side interconnect structure 206F and the two are pressed against each other to initiate a pre-bonding of the carrier substrate 220 to the front-side interconnect structure 206F. The pre-bonding may be performed at room temperature (e.g., between about 21° C. and about 25° C.). After the pre-bonding, an annealing process may be applied by, for example, heating the front-side interconnect structure 206F and the carrier substrate 220 to a temperature of in a range of 150° C. to 500° C. The annealing process drives triggers the formation of covalent bonds between the first bonding layer 218A and the second bonding layer 218B. After bonding, the first bonding layer 218A and the second bonding layer 218B may be collectively referred to as a bonding layer 218. Other bonding processes, such as ambient bonding, vacuum bonding, or the like may be used in other embodiments.

In FIG. 2C, the substrate 202 and the fins 203 are at least substantially replaced with the backside interconnect structure 206B. For example, the substrate 202 and the fins 203 may be substantially removed from the backside of the device layer 204 using one or more planarization processes (e.g., a chemical mechanical polish (CMP), or the like) and etch back processes. The etch back processes may be selective processes that etches the material of the substrate 202 and the fins 203 at a faster rate than a material of the gate stacks 212 or the epitaxial source/drain regions 208. In some embodiments, sacrificial masking layers may be formed as part of forming the device layer 204 to aid in the selective removal of the substrate 202 and the fins 203. In the illustrated embodiments, the substrate 202 and the fins 203 are completely removed. In other embodiments, a small portion of the substrate 202 and/or the fins 203 may remain.

After the substrate 202 and the fins 203 are substantially removed, a backside ILD 226 is deposited on the backside of the device layer 204. The backside ILD 226 may include one or more dielectric layers formed of materials such as silicon oxide, silicon oxynitride, silicon oxycarbonitiride, Phospho-Silicate Glass (PSG), Boro-Silicate Glass (BSG), Boron-Doped Phospho-Silicate Glass (BPSG), undoped Silicate Glass (USG), or the like. Backside conductive plugs 222 extend through the backside ILD 226 to electrically and physically couple the epitaxial source/drain regions 208. In some embodiments, silicide regions may be disposed at the interfaces between the backside conductive plugs 222 and the source/drain regions 208. The backside conductive plugs 222 may be formed of tungsten, cobalt, nickel, copper, silver, gold, aluminum, the like, or combinations thereof. The backside conductive plugs 222 allow for additional connections to be made to a backside of the device layer 204 for increased routing flexibility.

A backside interconnect structure 206B is formed over the backside ILD 226 and backside conductive plugs 222 on the backside of the device layer 204. The backside interconnect structure 206B may include, for example, metallization patterns in one or more dielectric layers. The metallization patterns include metal lines and vias formed in one or more low-k dielectric layers with damascene processes, for example. Specifically, the backside interconnect structure 206B may provide power delivery circuits to the devices of the device layer 204. For example, the backside interconnect structure 206B may include a power rail 224 (sometimes referred to as a backside power rail, super power rail, power rail structure, or the like) to provide power to the transistors of the device layer 204. Because the power rail 224 may be larger (e.g., wider and/or thicker) than signal lines of the front-side interconnect structure 206F, locating the power rail 224 in the backside interconnect structure 206B improves routing flexibility and allows for additional signal lines to be formed in the front-side interconnect structure 206F.

After the backside interconnect structure 206B is formed, the substrate 202 may be removed (e.g., with a planarization process), to expose the front-side interconnect structure so that an insulating bonding layer/bond pads (e.g., the insulating bonding layer 119 and the bond pads 117 of FIGS. 1A through 1D) may be formed over the front-side interconnect structure 206F for face-to-face bonding. In some embodiments, a second substrate (similar to the substrate 202, not explicitly illustrated) may be temporarily attached to the backside interconnect structure 206B while forming the insulating bonding layer/bond pads.

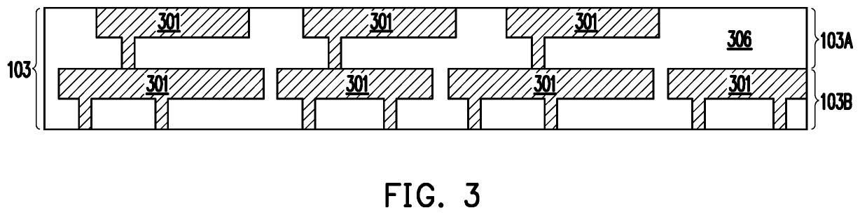

FIG. 3 illustrates the cross-sectional view of a metallization layer, e.g., a front-side interconnect structure 103 of the semiconductor die 115. FIG. 3 may also show the front-side interconnect structures 107 and 122. In some embodiments, the front-side interconnect structure 103 includes one or more connection layers, e.g., connection layers 103A and 103B. The front-side interconnect structure 103 that includes connection layers 103A and 103B include conductive connection lines 301 that are produced in a dielectric layer 306 and on top of the dielectric layer, which the dielectric layer 306 may include silicon dioxide.

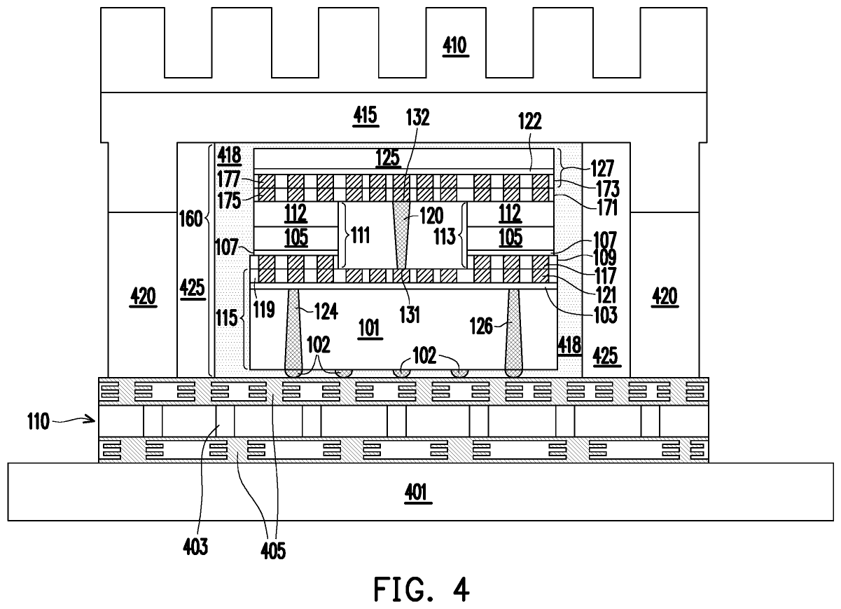

FIG. 4 illustrates the cross-sectional view of a semiconductor package, in accordance with some embodiments of the disclosure. FIG. 4 includes the package 160 of FIG. 1D that is disposed over the PCB 110 and the PCB 110 incudes one or more holes 403 for heat exchange to remove the heat produced by the package 160. The package 160 is disposed on the PCB 110 via a plurality of inductors 405 between the package 160 and the PCB 110. The PCB 110 is disposed on a carrier substrate 401 via a plurality of inductors 405 between the PCB 110 and the carrier substrate 401. FIG. 4 also shows a filler 425, e.g., a heat conductive filler, or air around the package 160 and heat conductive walls 415 and 420 around the filler 425. In some embodiments, the filler 425 is air or vacuum and in some other embodiments, the filler 425 is heat conductive. Also, a heat sink 410 is arranged over the heat conductive walls 415. In some embodiments, the package 160 is injected by a heat conductive filler 418 that also surrounds the package 160.

FIG. 4 also shows the bond pads 177 that also are used to receive the voltage and current generated by the integrated voltage regulator die 127. The integrated voltage regulator die 127 generates a regulated voltage, e.g., an essentially constant voltage, and also generates the required current such that the voltage does not fluctuate when the current changes. The generated regulated voltage and the generated current is transferred from the of bond pads 177, via the bond pads 175, to the backside interconnect structure 112 of semiconductor dies 111 and 113. The generated regulated voltage and the generated current is also transferred by the through vias 120 to the semiconductor die 115.

FIG. 5 illustrates the cross-sectional view of a semiconductor package, in accordance with some embodiments of the disclosure. FIG. 5 is similar to FIG. 1D where like reference numerals indicate like elements formed by like processes. Similar to FIG. 1D, The semiconductor package of FIG. 5 includes a semiconductor die 111 that is disposed over the semiconductor die 115 and the through vias 120 is outside the semiconductor die 111 and through the insulating layer 114, e.g., a dielectric layer or an encapsulant layer. A face-to-face bonding process couples the front-side interconnect structures 107 of the semiconductor die 111 to the front-side interconnect structure 103 of the semiconductor die 115. The face-to-face bonding includes the insulating bonding layer 109 having the bond pads 117 that are respectively bonded to the insulating bonding layer 119 having the bond pads 121 as also shown in FIGS. 1A through 1D.

The semiconductor package of FIG. 5 includes another semiconductor die 116 that includes the through vias 502 and 504 inside the semiconductor die 116 and does not include the backside interconnect structure 112. Also, the semiconductor die receives the power from the PCB 110 through a connector bumps 102 and the through vias 126. Specifically, the semiconductor die 116 includes a semiconductor substrate 505 having active devices disposed at a top surface of the semiconductor substrate 505, which are electrically connected together by a front-side interconnect structure 507 to form functional circuits (e.g., CPU circuitry, GPU circuitry, or the like). Through vias 502 and 504 extend through the semiconductor substrate 505 and electrically connect the front-side interconnect structure 507 to the backside (bottom surface) of the semiconductor die 116. The semiconductor die 116 may be bonded to the semiconductor die 115 in a face-to-back manner by a bonding between the backside of the semiconductor die 116 and the front-side interconnect structure 103 of the semiconductor die 115. The bonding, e.g., a face-to-back bonding, includes the insulating bonding layer 509 having the bond pads 517 that is directly bonded to the insulating bonding layer 519 having the bond pads 521 using a dielectric-to-dielectric and metal-to-metal bonding process similar to that described above with respect to bonding the semiconductor die 111 to the semiconductor die 115 in FIG. 1A. The bond pads 517 may be electrically connected to the front-side interconnect structure 507 by the through vias 502 and 504.

FIG. 6 illustrates a flow diagram of a process 600 for generating a packaged semiconductor device, according to some embodiments of the disclosure. The steps of the process are shown in FIGS. 1A, 1B, 1C, 1D, and 4. At step 610, a first semiconductor die is bonded, e.g., connected, to a second semiconductor die. As shown in FIGS. 1A and 1B, the top surface 143 of the semiconductor die 115 and the bottom surface 145 of the second semiconductor die 111 are bonded together. As shown, the semiconductor die 115 and the second semiconductor die 111 are bonded via the face-to-face bonding, e.g., a metal-to-metal bonding and dielectric-to-dielectric bonding. The face-to-face bonding is between two metallization layers, which are front-side interconnect structure 103 of the semiconductor die 115 and the front-side interconnect structure 107 of the second semiconductor die 111. In some embodiments, the width 106 of the semiconductor die 115 is longer than the width 108 of the second semiconductor die 111. The dielectric-to-dielectric bonding is between the insulating bonding layer 109 and the insulating bonding layer 119. The metal-to-metal bonding is between the bond pads 117 of the insulating bonding layer 109 and bond pads 121 of the insulating bonding layer 119.

At step 620, an insulating layer is deposited over the first semiconductor die and next to the second semiconductor die. As shown in FIG. 1B, an insulating layer 114 is deposited over the first semiconductor die 115 and next to the second semiconductor die 111.

At step 630, one or more through vias are formed in an insulating layer over the first semiconductor die. As shown in FIGS. 1B and 1E, one or more through vias 120 extend through the insulating layer 114 and are formed in the portion 137 over the semiconductor die 115. As shown in FIG. 1B, the through vias 120 extends the height of the insulating layer 114. Forming the through vias, as shown in FIGS. 1B and 1C, makes the first ends 131 of the through vias 120 to be electrically coupled to the front-side interconnect structure 103 at the top surface 143 of the semiconductor die 115. Thus, the first end 131 is connected to the bond pads 121 and through the bond pads 121 to the front-side interconnect structure 103. Also, makes the second ends 132 of the through vias 120 to be electrically coupled to the backside interconnect structure 112 at the top surface 147 of the second semiconductor die 111. Thus, the second end 132 is connected to the bond pads 175 and, thus, to the backside interconnect structure 112 of the semiconductor dies 111. In some embodiments, the portion 137 is next to the semiconductor die 111.

At step 640, an integrated voltage regulator die is bonded over the second semiconductor die and the insulating layer. As shown in FIG. 1C, the integrated voltage regulator die 127 is bonded over the second semiconductor die 111 and the insulating layer 114. A second end 132, opposite to the first end 131, of at least one through via 120 is electrically connected to the power rail structure of the first backside interconnect structure 112 of the second semiconductor die 111. In some embodiments, the power rail structure has connection lines similar to the conductive connection lines 301 but are about 2-3 times wider to reduce ohmic loss.

In the embodiments disclosed herein, the through vias 120 are arranged outside the top semiconductor die that includes the top semiconductor device. As such, the processing steps, the size, and the cost of packaging may be reduced and also the form factor may be improved.

As such, the packaged semiconductor may be used in advanced networking and server applications (e.g., AI (Artificial Intelligence)) which operate with high data rates, high bandwidth demands and low latency. Furthermore, the packaged semiconductor device may be provided with a high degree of chip package integration in a small form factor.

According to an embodiment, a semiconductor package includes a first semiconductor die and a second semiconductor die bonded over the first semiconductor die. The second semiconductor die includes a first backside interconnect structure having a first power rail structure. The semiconductor package also includes an integrated voltage regulator die bonded over the second semiconductor die and a first through via on the first semiconductor die and electrically coupled to the first semiconductor die. The first through via is disposed outside of and adjacent to the second semiconductor die and the first through via electrically couples the first semiconductor die to the first power rail structure of the second semiconductor die through the integrated voltage regulator die.

In an embodiment, the semiconductor package further includes a second through via on the first semiconductor die and a third semiconductor die that includes a second backside interconnect structure having a second power rail structure that is bonded over the first semiconductor die. The first through via and the second through via are disposed between the second semiconductor die and the third semiconductor die and the second through via electrically couples the first semiconductor die to second power rail structure of the third semiconductor die through the integrated voltage regulator die. In an embodiment, the semiconductor package further includes an insulating layer on the first semiconductor die between the second semiconductor die and the third semiconductor die such that the first through via and the second through via extend through the insulating layer. In an embodiment, the first semiconductor die further includes one or more connector bumps connected to a bottom side of the first semiconductor die and one or more third through vias that are extended between a connector bump and at bottom of the first semiconductor die to a first front-side interconnect structure of the first semiconductor die. In an embodiment, the semiconductor package further includes a fourth semiconductor die that includes a second front-side interconnect structure and one or more second vias such that the fourth semiconductor die is bonded over the first semiconductor die. The second front-side interconnect structure is away from the first semiconductor die, the first through via is arranged between the second and fourth semiconductor dies, and the one or more second vias electrically connect the first front-side interconnect structure of the first semiconductor die to the second front-side interconnect structure of the fourth semiconductor die. In an embodiment, the integrated voltage regulator die is bonded over the second semiconductor die by dielectric-to-dielectric and metal-to-metal bonding. In an embodiment, the integrated voltage regulator die provides electrical power to the second semiconductor die.

According to an embodiment, a semiconductor package includes a first semiconductor die that includes a first front-side interconnect structure. The semiconductor package includes a second semiconductor die and a third semiconductor die, separated by a distance, that are bonded over the first semiconductor die. The second semiconductor die includes a first backside interconnect structure having a first power rail structure and the third semiconductor die includes a second backside interconnect structure having a second power rail structure. The semiconductor package also includes an integrated voltage regulator die bonded over the second semiconductor die and the third semiconductor die such that the integrated voltage regulator die is electrically connected to the first power rail structure and the second power rail structure. The semiconductor package further includes one or more through vias arranged on the first front-side interconnect structure of the first semiconductor die and the one or more through vias electrically couple the first power rail structure and the second power rail structure to the first front-side interconnect structure of the first semiconductor die.

In an embodiment, the semiconductor package further includes an insulating layer on the first semiconductor die in the distance between the second semiconductor die and the third semiconductor die such that the one or more through vias extend through the insulating layer. In an embodiment, the semiconductor package further includes a first insulating bonding layer over the second semiconductor die and the third semiconductor die and first bond pads in the first insulating bonding layer such that the one or more through vias extend from the first bond pads to the first semiconductor die. In an embodiment, the integrated voltage regulator includes a second front-side interconnect structure and a second insulating bonding layer connected to the second front-side interconnect structure. The second insulating bonding layer includes second bond pads, the second insulating bonding layer is directly bonded to the first insulating bonding layer, and the second bond pads are directly bonded to the first bond pads. In an embodiment, the one or more through vias are arranged in the distance between the second semiconductor die and the third semiconductor die. In an embodiment, the one or more through vias are arranged on an opposite side of the second semiconductor die with respect to the third semiconductor die. In an embodiment, the semiconductor package further includes a plurality of connector bumps connected to a side of the first semiconductor die opposite to the first front-side interconnect structure and a plurality of second through vias extending between the first front-side interconnect structure and the plurality of connector bumps.

According to an embodiment, a method of packaging includes bonding a first semiconductor die to a second semiconductor die such that the first semiconductor die includes a first front-side interconnect structure and the second semiconductor die includes a first backside interconnect structure having a first power rail structure. The method also includes depositing an insulating layer over the first semiconductor die and next to the second semiconductor die and forming a first through via in the insulating layer such that a first end of the first through via is electrically coupled to the first front-side interconnect structure of first semiconductor die. The method further includes bonding an integrated voltage regulator die over the second semiconductor die and the insulating layer such that a second end, opposite to the first end, of the first through via is electrically connected, through the integrated voltage regulator die, to the first power rail structure in the first backside interconnect structure of the second semiconductor die.

In an embodiment, bonding the first semiconductor die to the second semiconductor die includes dielectric-to-dielectric bonding and metal-to-metal bonding. In an embodiment, the dielectric-to-dielectric bonding includes bonding a first insulating bonding layer between a second front-side interconnect structure of the second semiconductor die and a second insulating bonding layer on the first front-side interconnect structure of the first semiconductor die, and the metal-to-metal bonding includes electrically connecting first bond pads in the first insulating bonding layer to second bond pads in the second insulating bonding layer. In an embodiment, the method of packaging further includes bonding a second front-side interconnect structure of a third semiconductor die to the first front-side interconnect structure of the first semiconductor die such that the third semiconductor die incudes a second backside interconnect structure having a second power rail structure, bonding the integrated voltage regulator die over the third semiconductor die, and forming a second through via in the insulating layer. A first end of the second through via is electrically coupled to the first front-side interconnect structure of the first semiconductor die, and a second end, opposite to the first end, of the second through via is electrically connected, through the integrated voltage regulator die, to the second power rail structure in the second backside interconnect structure of the third semiconductor die. In an embodiment, the method of packaging further includes bonding a backside of a third semiconductor die to the first front-side interconnect structure of the first semiconductor die. The third semiconductor die includes second through vias that electrically connect the first front-side interconnect structure of the first semiconductor die to a second front-side interconnect structure of the third semiconductor die. In an embodiment, the method of packaging further includes forming a plurality of third through vias in the first semiconductor die and coupling a plurality of connector bumps to a side of the first semiconductor die opposite to the first front-side interconnect structure such that the third through vias electrically connect the first front-side interconnect structure to the plurality of connector bumps.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a first semiconductor die;
a second semiconductor die bonded over the first semiconductor die, wherein the second semiconductor die comprises a first backside interconnect structure having a first power rail structure;
an integrated voltage regulator die bonded over the second semiconductor die; and
a first through via on the first semiconductor die and electrically coupled to the first semiconductor die, wherein the first through via is disposed outside of and adjacent to the second semiconductor die, and wherein the first through via electrically couples the first semiconductor die to the first power rail structure of the second semiconductor die through the integrated voltage regulator die.

2. The semiconductor package of claim 1, further comprising:
a second through via on the first semiconductor die; and
a third semiconductor die that comprises a second backside interconnect structure having a second power rail structure that is bonded over the first semiconductor die, wherein the first through via and the second through via are disposed between the second semiconductor die and the third semiconductor die, and wherein the second through via electrically couples the first semiconductor die to second power rail structure of the third semiconductor die through the integrated voltage regulator die.

3. The semiconductor package of claim 2, further comprising:
an insulating layer on the first semiconductor die between the second semiconductor die and the third semiconductor die, wherein the first through via and the second through via extend through the insulating layer.

4. The semiconductor package of claim 1, wherein the first semiconductor die further comprises:
one or more connector bumps connected to a bottom side of the first semiconductor die; and
one or more third through vias extended between a connector bump and at bottom of the first semiconductor die to a first front-side interconnect structure of the first semiconductor die.

5. The semiconductor package of claim 4, further comprising:
a fourth semiconductor die comprising a second front-side interconnect structure and one or more second vias, wherein the fourth semiconductor die is bonded over the first semiconductor die, wherein the second front-side interconnect structure is away from the first semiconductor die, wherein the first through via is arranged between the second and fourth semiconductor dies, and wherein the one or more second vias electrically connect the first front-side interconnect structure of the first semiconductor die to the second front-side interconnect structure of the fourth semiconductor die.

6. The semiconductor package of claim 1, wherein the integrated voltage regulator die is bonded over the second semiconductor die by dielectric-to-dielectric and metal-to-metal bonding.

7. The semiconductor package of claim 6, wherein the integrated voltage regulator die is configured to provide electrical power to the second semiconductor die.

8. A semiconductor package comprising:
a first semiconductor die that comprises a first front-side interconnect structure;
a second semiconductor die and a third semiconductor die, separated by a distance, bonded over the first semiconductor die, wherein the second semiconductor die comprises a first backside interconnect structure having a first power rail structure and the third semiconductor die comprises a second backside interconnect structure having a second power rail structure;
an integrated voltage regulator die bonded over the second semiconductor die and the third semiconductor die, the integrated voltage regulator die being electrically connected to the first power rail structure and the second power rail structure; and
one or more through vias arranged on the first front-side interconnect structure of the first semiconductor die, and wherein the one or more through vias electrically couple the first power rail structure and the second power rail structure to the first front-side interconnect structure of the first semiconductor die.

9. The semiconductor package of claim 8, further comprising:
an insulating layer on the first semiconductor die in the distance between the second semiconductor die and the third semiconductor die, wherein the one or more through vias extend through the insulating layer.

10. The semiconductor package of claim 8, further comprising:
a first insulating bonding layer over the second semiconductor die and the third semiconductor die; and
first bond pads in the first insulating bonding layer, wherein the one or more through vias extend from the first bond pads to the first semiconductor die.

11. The semiconductor package of claim 10, wherein the integrated voltage regulator comprises a second front-side interconnect structure and a second insulating bonding layer connected to the second front-side interconnect structure, wherein the second insulating bonding layer comprises second bond pads, wherein the second insulating bonding layer is directly bonded to the first insulating bonding layer, and wherein the second bond pads are directly bonded to the first bond pads.

12. The semiconductor package of claim 11, wherein the one or more through vias are arranged in the distance between the second semiconductor die and the third semiconductor die.

13. The semiconductor package of claim 8, wherein the one or more through vias are arranged on an opposite side of the second semiconductor die with respect to the third semiconductor die.

14. The semiconductor package of claim 8, further comprising:
a plurality of connector bumps connected to a side of the first semiconductor die opposite to the first front-side interconnect structure; and
a plurality of second through vias extending between the first front-side interconnect structure and the plurality of connector bumps.

15. A method of packaging, comprising:
bonding a first semiconductor die to a second semiconductor die, wherein the first semiconductor die comprises a first front-side interconnect structure, and wherein the second semiconductor die comprises a first backside interconnect structure having a first power rail structure;
depositing an insulating layer over the first semiconductor die and next to the second semiconductor die;
forming a first through via in the insulating layer, wherein a first end of the first through via is electrically coupled to the first front-side interconnect structure of first semiconductor die; and
bonding an integrated voltage regulator die over the second semiconductor die and the insulating layer, wherein a second end, opposite to the first end, of the first through via is electrically connected, through the integrated voltage regulator die, to the first power rail structure in the first backside interconnect structure of the second semiconductor die.

16. The method of claim 15, wherein bonding the first semiconductor die to the second semiconductor die comprises dielectric-to-dielectric bonding and metal-to-metal bonding.

17. The method of claim 16, wherein the dielectric-to-dielectric bonding comprises bonding a first insulating bonding layer between a second front-side interconnect structure of the second semiconductor die and a second insulating bonding layer on the first front-side interconnect structure of the first semiconductor die, and wherein the metal-to-metal bonding comprises electrically connecting first bond pads in the first insulating bonding layer to second bond pads in the second insulating bonding layer.

18. The method of claim 15, further comprising:
bonding a second front-side interconnect structure of a third semiconductor die to the first front-side interconnect structure of the first semiconductor die, wherein the third semiconductor die comprises a second backside interconnect structure having a second power rail structure;
bonding the integrated voltage regulator die over the third semiconductor die; and
forming a second through via in the insulating layer, wherein a first end of the second through via is electrically coupled to the first front-side interconnect structure of the first semiconductor die, and wherein a second end, opposite to the first end, of the second through via is electrically connected, through the integrated voltage regulator die, to the second power rail structure in the second backside interconnect structure of the third semiconductor die.

19. The method of claim 15, further comprising:
bonding a backside of a third semiconductor die to the first front-side interconnect structure of the first semiconductor die, wherein the third semiconductor die comprises second through vias that electrically connect the first front-side interconnect structure of the first semiconductor die to a second front-side interconnect structure of the third semiconductor die.

20. The method of claim 15, further comprising:
forming a plurality of third through vias in the first semiconductor die; and
coupling a plurality of connector bumps to a side of the first semiconductor die opposite to the first front-side interconnect structure, wherein the third through vias electrically connect the first front-side interconnect structure to the plurality of connector bumps.
